(19) United States
(12) Patent Application Publication
(10) Pub. No.: US 2004/0140548 A1
(43) Pub. Date: Jul. 22, 2004

(54) Modular debugger to adapt various chip sizes and logic analyzers

(76) Inventors: Wenjun Chen, Fremont, CA (US); William W. Ruckman, San Jose, CA (US); David K. Kim, San Jose, CA (US)

Correspondence Address: BLAKELY, SOKOLOFF, TAYLOR & ZAFMAN LLP, Seventh Floor, 12400 Wilshire Boulevard, Los Angeles, CA, 90025-1026, US

(21) Appl. No.: 10/348,869

(22) Filed: Jan. 22, 2003

(51) Int. Cl. H01L 23/52

(52) U.S. Cl. 257/691

(57) ABSTRACT

Disclosed are novel methods and apparatus for provision of a modular debugger to adapt various chip sizes and/or signal analyzers. In an embodiment of the present invention, an integrated circuit (IC) assembly is disclosed. The IC assembly includes: a printed circuit board (PCB); a plurality of flex circuit connections electrically coupled to the PCB; a carrier electrically coupled to the PCB; a socket electrically coupled to the carrier; an application specific IC (ASIC) electrically coupled to the socket; and a PCB adapter card electrically couplable to at least one of the plurality of flex circuit connections. In another embodiment of the present invention, the PCB adapter card may include at least one connector to provide a communication channel between the ASIC and a signal analyzer.

### FIELD OF INVENTION

The present invention generally relates to the field of integrated circuits (ICs). More specifically, an embodiment of the present invention relates to a modular-type debugger designed to adapt various chip sizes and/or signal analyzers.

### BACKGROUND OF INVENTION

FIG. 1 illustrates an exemplarily flow diagram of a typical design process 100 for ICs in accordance with the prior art. The process can be generally divided into a front end design phase and a back end development phase. During the front end phase, an engineer designs and develops a logical representation of an integrated circuit (IC) from a set of specifications in form of a schematic (stage 102). At a stage 104, the schematic is loaded into a computer from which a circuit netlist is generated. The netlist defines the entire IC design including all components and interconnections.

Moreover, the IC information may be developed using hardware description language (HDL) and synthesis. With the aid of circuit simulation tools available on computers, a designer can then simulate the functionality of a given circuit at a stage 106. The circuit simulation process may involve several iterations of design modifications and improvements, until the circuit design is finalized at a stage 108.

The back end development involves several stages during which a final circuit layout (physical description) is developed based on the schematic design of the front end. In a stage 110, various building blocks (or cells), as defined by the finalized circuit schematic, are placed within a predefined floor plan. For ICs designed based on array or standard cell technology, the various building circuit blocks are typically pre-defined and made available in a cell library. For example, during the stage 110, a plurality of cells are selected from one or more cell libraries and the cell interconnects are determined. More particularly, groups of cells may be interconnected to function as a flip-flop, shift registers, and the like. The routing of wires to interconnect the cells and achieve the aforementioned goals is preformed during a routing stage 112, typically referred to as conducting paths, wires or nets. Accordingly, in the stage 112, interconnects between circuit elements are routed throughout the layout. In a stage 114, the accuracy of the layout is verified against the schematic and if no errors or design rule violations are found at a stage 116, the circuit layout information is used for the process of fabrication in a stage 118.

As discussed with respect to FIG. 1, a typical IC design may involve a number of complicated steps prior to actual fabrication (118). As the number of modules within each IC design increases (to, for example, add functionality), typical IC design techniques, however, often fail to guarantee a properly operating part. Also, additional issues may be introduced during the fabrication stage 118, for example, as a result of contaminants or process failures. Therefore, it becomes necessary to debug or test a chip after fabrication. Logic analyzers and oscilloscopes may be utilized to debug a chip. Each of these logic analyzers or oscilloscopes may use different types of connectors and cable assemblies for their interface. However, with the ever-changing interfaces (for example, to improve communication speeds or as a result of using different standards), ease and the speed of accessing each signal access point on a target chip is of utmost importance. Also, with faster communication speeds, maintaining signal quality during the debugging steps becomes even more essential.

### SUMMARY OF INVENTION

The present invention, which may be utilized in a general-purpose digital computer, in certain embodiments, includes novel methods and apparatus to provide a modular-type debugger designed to adapt various chip sizes and/or signal analyzers. In an embodiment of the present invention, an integrated circuit (IC) assembly is disclosed. The IC assembly includes: a printed circuit board (PCB); a plurality of flex circuit connections electrically coupled to the PCB; a carrier electrically coupled to the PCB; a socket electrically coupled to the carrier; an application specific IC (ASIC) electrically coupled to the socket; and a PCB adapter card electrically couplable to at least one of the plurality of flex circuit connections.

In another embodiment of the present invention, the PCB adapter card may include at least one connector to provide a communication channel between the ASIC and a signal analyzer.

In a further embodiment of the present invention, only the carrier needs to be changed for a different type of ASIC.

In yet another embodiment of the present invention, only the PCB adapter card needs to be changed for a different type of signal analyzer.

### BRIEF DESCRIPTION OF DRAWINGS

The present invention may be better understood and its numerous objects, features, and advantages made apparent to those skilled in the art by reference to the accompanying drawings in which:

FIG. 1 illustrates an exemplarily flow diagram of a typical design process 100 for ICs in accordance with the prior art;

FIG. 2 illustrates an exemplary computer system 200 in which the present invention may be embodied;

FIG. 3A illustrates an exemplary vertical side view of an IC assembly 300 in accordance with an embodiment of the present invention;

FIG. 3B illustrates an exemplary top view of an IC assembly 350 in accordance with an embodiment of the present invention;

FIG. 4A illustrates an exemplary horizontal side view of an IC assembly 400 in accordance with an embodiment of the present invention;

FIG. 4B illustrates an exemplary horizontal side view of the IC section 450 of FIG. 4A in accordance with an embodiment of the present invention;

FIG. 5A illustrates an exemplary exploded top view of an IC assembly 500 in accordance with an embodiment of the present invention; and

FIG. 5B illustrates an exemplary exploded bottom view of an IC assembly 550 in accordance with an embodiment of the present invention.

The use of the same reference symbols in different drawings indicates similar or identical items.

### DETAILED DESCRIPTION

In the following description, numerous details are set forth. It will be apparent, however, to one skilled in the art that embodiments of the invention may be practiced without these specific details. In other instances, well-known structures, devices, and techniques have not been shown in detail, in order to avoid obscuring the understanding of the description. The description is thus to be regarded as illustrative instead of limiting.

Reference in the specification to “one embodiment” or “an embodiment” means that a particular feature, structure, or characteristic described in connection with the embodiment is included in at least an embodiment of the invention. The appearances of the phrase “in one embodiment” in various places in the specification are not necessarily all referring to the same embodiment.

In addition, select embodiments of the present invention include various operations, which are described herein. The operations of the embodiments of the present invention may be performed by hardware components or may be embodied in machine-executable instructions, which may be in turn utilized to cause a general-purpose or special-purpose processor, or logic circuits programmed with the instructions to perform the operations. Alternatively, the operations may be performed by a combination of hardware and software.

Moreover, embodiments of the present invention may be provided as computer program products, which may include machine-readable medium having stored thereon instructions used to program a computer (or other electronic devices) to perform a process according to embodiments of the present invention. The machine-readable medium may include, but is not limited to, floppy diskettes, optical disks, compact disc-read only memories (CD-ROMs), and magneto-optical disks, read-only memories (ROMs), random-access memories (RAMs), erasable programmable ROMs (EPROMs), electrically EPROMs (EEPROMs), magnetic or optical cards, flash memory, or other types of media or machine-readable medium suitable for storing electronic instructions and/or data.

Additionally, embodiments of the present invention may be downloaded as a computer program product, wherein the program may be transferred from a remote computer (e.g., a server) to a requesting computer (e.g., a client) by way of data signals embodied in a carrier wave or other propagation medium via a communication link (e.g., a modem or network connection). Accordingly, herein, a carrier wave shall be regarded as comprising a machine-readable medium.

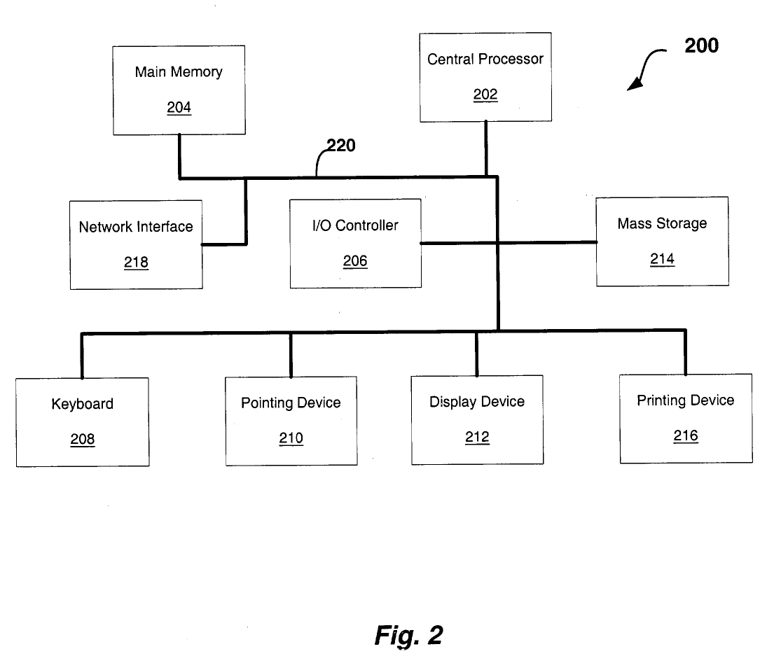

FIG. 2 illustrates an exemplary computer system 200 in which the present invention may be embodied in certain embodiments. The system 200 comprises a central processor 202, a main memory 204, an input/output (I/O) controller 206, a keyboard 208, a pointing device 210 (e.g., mouse, track ball, pen device, or the like), a display device 212, a mass storage 214 (e.g., a nonvolatile storage such as a hard disk, an optical drive, and the like), and a network interface 218. Additional input/output devices, such as a printing device 216, may be included in the system 200 as desired. As illustrated, the various components of the system 200 communicate through a system bus 220 or similar architecture.

In an embodiment, the computer system 200 includes a Sun Microsystems computer utilizing a SPARC microprocessor available from several vendors (including Sun Microsystems of Santa Clara, Calif.). Those with ordinary skill in the art understand, however, that any type of computer system may be utilized to embody the present invention, including those made by Hewlett Packard of Palo Alto, Calif., and IBM-compatible personal computers utilizing Intel microprocessor, which are available from several vendors (including IBM of Armonk, N.Y.). In addition, instead of a single processor, two or more processors (whether on a single chip or on separate chips) can be utilized to provide speedup in operations. It is further envisioned that the processor 202 may be a complex instruction set computer (CISC) microprocessor, a reduced instruction set computing (RISC) microprocessor, a very long instruction word (VLIW) microprocessor, a processor implementing a combination of instruction sets, and the like.

The network interface 218 provides communication capability with other computer systems on a same local network, on a different network connected via modems and the like to the present network, or to other computers across the Internet. In various embodiments, the network interface 218 can be implemented utilizing technologies including, but not limited to, Ethernet, Fast Ethernet, wide-area network (WAN), leased line (such as T1, T3, optical carrier 3 (OC3), and the like), analog modem, digital subscriber line (DSL and its varieties such as high bit-rate DSL (HDSL), integrated services digital network DSL (IDSL), and the like), cellular, wireless networks (such as those implemented by utilizing the wireless application protocol (WAP)), time division multiplexing (TDM), universal serial bus (USB and its varieties such as USB 2.0), asynchronous transfer mode (ATM), satellite, cable modem, and/or FireWire.

Moreover, the computer system 200 may utilize operating systems such as Solaris, Windows (and its varieties such as CE, NT, 2000, XP, ME, and the like), HP-UX, IBM-AIX, PALM, UNIX, Berkeley software distribution (BSD) UNIX, Linux, Apple UNIX (AUX), and the like. Also, it is envisioned that in certain embodiments, the computer system 200 is a general purpose computer capable of running any number of applications such as those available from companies including Oracle, Siebel, Unisys, Microsoft, and the like.

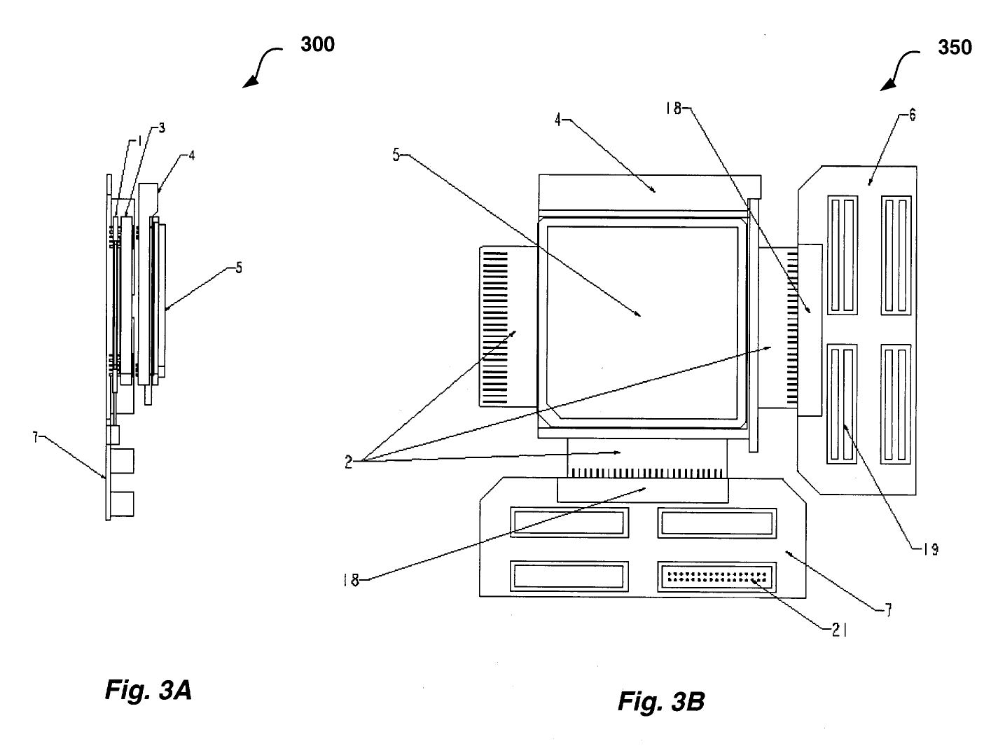

FIG. 3A illustrates an exemplary vertical side view of an IC assembly 300 in accordance with an embodiment of the present invention. In one embodiment of the present invention, the IC assembly 300 may be utilized in the computer system 200 of FIG. 2. The IC assembly 300 includes a main printed circuit board (PCB) (1), a carrier (3), a socket (4), an application specific IC (ASIC) (5), and a PCB adapter card (7). In an embodiment of the present invention, the socket (4) may be a ball grid array-type (BGA-type) zip socket, which can directly plug into the ASIC (5). In a further embodiment of the present invention, the carrier (3) may directly mount the BGA-type zip socket (4). In one embodiment of the present invention, the PCB adapter card (7) may directly plug into the main PCB (1) to provide an interface to a logic analyzer and/or an oscilloscope. In an embodiment of the present invention, the CPU may be a metal-programmed gate array (mPGA) CPU, which may be plugged directly into the socket (4).

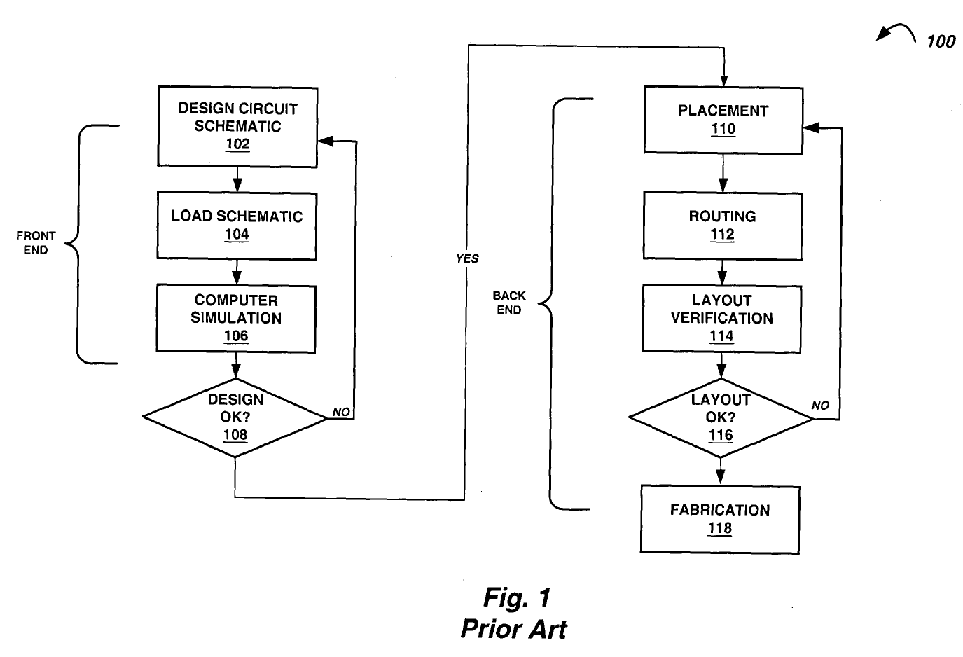

In another embodiment of the present invention, the ASIC (5) may be any IC such as available CPUs on the market including those discussed with respect to the central processor 102 of FIG. 1. In a further embodiment of the present invention, the IC assembly 300 may be utilized with the JBus architecture available from Sun Microsystems of Santa Clara, Calif. Generally, the JBus architecture is directed at multiprocessor systems (e.g., 64-bit four-way or eight-way symmetric multiprocessing (SMP) systems). Currently, the JBus architecture supports a 128-bit packet-switched, split-transaction request and data bus.

FIG. 3B illustrates an exemplary top view of an IC assembly 350 in accordance with an embodiment of the present invention. In one embodiment of the present invention, the IC assembly 350 may be the same or similar to the IC assembly 300 of FIG. 3A. The IC assembly 350 includes one or more flex circuit connections (2), the socket (4), the ASIC (5), another PCB adapter card (6), the PCB adapter card (7), a flex connector (18) (e.g., to receive the flex circuit connections (2)), a matched impedance blade-connector (19), and a socket connector (21). In one embodiment of the present invention, ribbon cables may be utilized to establish an interface between the socket connector (21) and a logic analyzer and/or an oscilloscope. In a further embodiment of the present invention, the matched impedance blade connectors (19) may provide a matched impedance such that communication signals (such as those discussed with respect to the computer system 200 of FIG. 2) are properly terminated (e.g., to limit signal echoes which may hinder successful communication between the ASIC (5) and a logic analyzer and/or an oscilloscope).

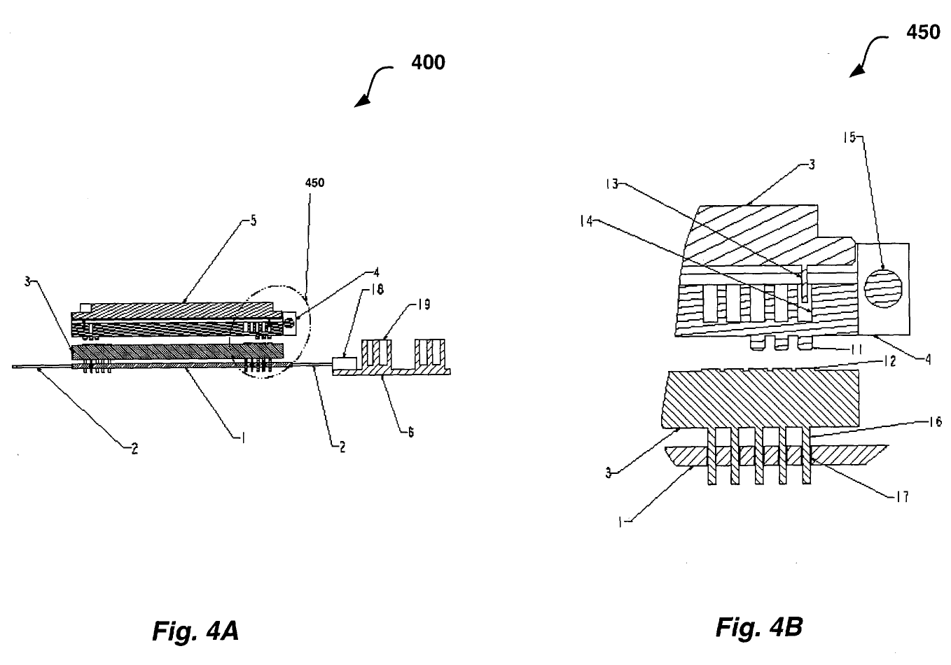

FIG. 4A illustrates an exemplary horizontal side view of an IC assembly 400 in accordance with an embodiment of the present invention. In one embodiment of the present invention, the IC assembly 400 may be the same or similar to the IC assemblies 300 and 350 discussed with respect to FIGS. 3A and 3B. The IC assembly 400 includes the main PCB (1), the flex circuit connection(s) (2), the carrier (3), the socket (4), the ASIC (5), the PCB adapter card (6), the flex connector (18), and the blade connector (19). An IC section 450 of the IC assembly 400 will be further discussed with respect to the FIG. 4B.

FIG. 4B illustrates an exemplary horizontal side view of the IC section 450 of FIG. 4A in accordance with an embodiment of the present invention. The IC section 450 includes the main PCB (1), the carrier (3), the socket (4), one or more solder balls (11), one or more solder pads (12) (e.g., on top of the carrier (3)), one or more pins (13), one or more pin receptacles (14) (e.g., to receive the pins (13)), a handle (15) (e.g., to lock the socket (4)), one or more carrier pins (16), and one or more main PCB holes (17) (e.g., to receive the carrier pins (16)). In one embodiment of the present invention, the solder balls (11) may be soldered to solder pads (12). In another embodiment of the present invention, the carrier pins (16) may also be soldered to the main PCB holes (17) by, for example, utilizing solder rings (e.g., to avoid contaminating the carrier pins (16)). The soldering may be further accomplished by whip soldering, solder balls, and the like.

In a further embodiment of the present invention, surface mount technology (SMT) may be utilized to solder pads (12) on top of the carrier (3). It is envisioned that such an embodiment may further facilitate mounting a BGA socket (4 & 11) on to the carrier (3). In accordance with various embodiments of the present invention, it is envisioned that the solder balls (11) and solder pads (12) may be soldered prior to, at the same time as, or after soldering the carrier pins (16) and the main PCB holes (17), for example, depending on their respective thermal profile and/or melting point of the soldering material used.

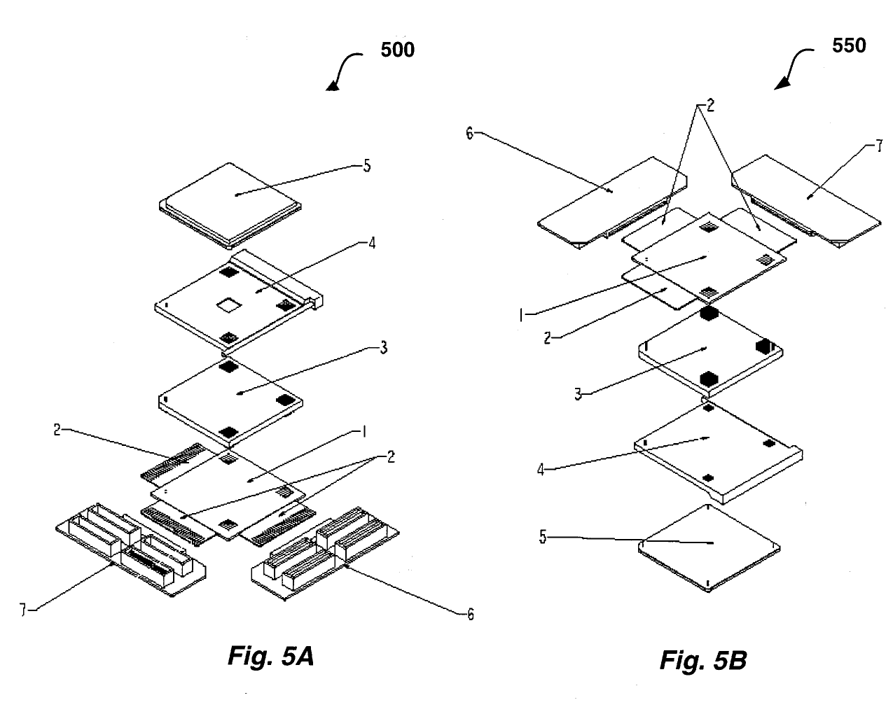

FIG. 5A illustrates an exemplary exploded top view of an IC assembly 500 in accordance with an embodiment of the present invention. In one embodiment of the present invention, the IC assembly 500 may be the same or similar to the IC assemblies 300, 350, 400, and 450 discussed with respect to FIGS. 3A through 4B. The IC assembly 500 includes the main PCB (1), the flex circuit connection(s) (2), the carrier (3), the socket (4), the ASIC (5), and the PCB adapter cards (6 and 7).

FIG. 5B illustrates an exemplary exploded bottom view of an IC assembly 550 in accordance with an embodiment of the present invention. In one embodiment of the present invention, the IC assembly 550 may be the same or similar to the IC assemblies 300, 350, 400, 450, and 500 discussed with respect to FIGS. 3A through 5A. The IC assembly 550 includes the main PCB (1), the flex circuit connection(s) (2), the carrier (3), the socket (4), the ASIC (5), and the PCB adapter cards (6 and 7). Even though the flex circuit connection(s) (2) are illustrated with connectors only on the top side, it is envisioned that the connectors may be present on the bottom side only or both the top and the bottom sides.

Accordingly, a device built in accordance with various embodiments of the present invention is envisioned to allow engineers to connect probes from each signal access points on the target system to a logic analyzer or oscilloscope to allow debugging of the ASIC prior to the mass production. In one embodiment of the present invention, the modular type debugger may be BGA compatible. In a further embodiment of the present invention, the modular type debugger may be able to adapt various ASIC sizes and/or logic analyzers. For example, for different ASIC sizes or types, the utilized carrier (3) may be merely changed. Additionally, utilizing certain embodiments of the present invention is envisioned to readily permit utilization of different types of logic analyzers and/or oscilloscopes (for example, with different types of probes) by merely changing the utilized adapter cards (6 or 7).

In one embodiment of the present invention, the main PCB (1) may include one or more hybrid flex circuit connections (2), which may be integrated into the main PCB (1). In a further embodiment of the present invention, the PCB adapter cards (6 & 7) may include flex connector (18), the different type of connectors (19 & 21) such as a matched impedance blade connector (19), and/or a standard pin and socket connector (21), so it can transfer the signals from the ASIC (5) to various types of logic analyzers or oscilloscopes. In another embodiment of the present invention, the flex circuit connections (2) can be directly plugged into the flex connector (18) on the PCB adapter card (6 & 7) to carry the signals to a logic analyzer, for example.

The foregoing description has been directed to specific embodiments of the present invention. It will be apparent to those with ordinary skill in the art that modifications may be made to the described embodiments of the present invention, with the attainment of all or some of the advantages. For example, the techniques of the present invention may be utilized in set-top boxes, blade computers, electronic gaming apparatus (such as those provided by Microsoft Corporation of Redmond, Wash. (e.g., XBOX game machine) and Sony Corporation of Japan (e.g., PlayStation game machine)), and devices available from SONICblue Inc. of Santa Clara, Calif. (such as ReplayTV and Rio MP3 players), and the like.

Additionally, even though certain embodiments of the present invention have been discussed with reference to logic analyzers and/or oscilloscopes, it is envisioned that any type of device capable of receiving test signals may be utilized such as boundary scan tool and the like. Therefore, it is the object of the appended claims to cover all such variations and modifications as come within the spirit and scope of the invention.

What is claimed is:

1. An integrated circuit (IC) assembly comprising:
a printed circuit board (PCB);
a plurality of flex circuit connections electrically coupled to the PCB;
a carrier electrically coupled to the PCB;
a socket electrically coupled to the carrier;
an application specific IC (ASIC) electrically coupled to the socket; and
a PCB adapter card electrically couplable to at least one of the plurality of flex circuit connections, the PCB adapter card including at least one connector to provide a communication channel between the ASIC and a signal analyzer.

2. The IC assembly of claim 1 wherein only the carrier needs to be changed for a different type of ASIC.

3. The IC assembly of claim 1 wherein the signal analyzer is selected from a group comprising a logic analyzer and an oscilloscope.

4. The IC assembly of claim 1 wherein only the PCB adapter card needs to be changed for a different type of signal analyzer.

5. The IC assembly of claim 1 wherein the socket is a BGA-type socket.

6. The IC assembly of claim 1 wherein the ASIC is a central processing unit (CPU).

7. The IC assembly of claim 6 wherein the CPU is an mPGA-type CPU.

8. The IC assembly of claim 6 wherein the CPU is selected from a group comprising a complex instruction set computer (CISC) microprocessor, a reduced instruction set computing (RISC) microprocessor, a very long instruction word (VLIW) microprocessor, and a processor implementing a combination of instruction sets.

9. The IC assembly of claim 6 wherein the CPU is implemented in a JBus architecture.

10. The IC assembly of claim 1 wherein the PCB and the carrier are soldered together.

11. The IC assembly of claim 10 wherein the soldering is accomplished by a technique selected from a group comprising whip soldering, solder balls, solder rings, and surface mount technology.

12. The IC assembly of claim 1 wherein the electrical couplings are established by a plurality of pins and pin receptacles.

13. The IC assembly of claim 12 wherein the plurality of pin receptacles are holes.

14. The IC assembly of claim 1 wherein the plurality of flex circuit connections are physically coupled to the PCB.

15. The IC assembly of claim 1 wherein the PCB adapter card includes a matched impedance blade connector to maintain signal integrity.

16. A computer system comprising:
a printed circuit board (PCB);
a plurality of flex circuit connections electrically coupled to the PCB;
a carrier electrically coupled to the PCB;
a socket electrically coupled to the carrier;
a central processing unit (CPU) electrically coupled to the socket; and
a PCB adapter card electrically couplable to at least one of the plurality of flex circuit connections, the PCB adapter card including at least one connector to provide a communication channel between the CPU and a signal analyzer.

17. The computer system of claim 16 wherein only the carrier needs to be changed for a different type of CPU.

18. The computer system of claim 16 wherein the signal analyzer is selected from a group comprising a logic analyzer and an oscilloscope.

19. The computer system of claim 16 wherein only the PCB adapter card needs to be changed for a different type of signal analyzer.

20. The computer system of claim 16 wherein the socket is a BGA-type socket.

21. The computer system of claim 16 wherein the CPU is an mPGA-type CPU.

22. The computer system of claim 16 wherein the CPU is selected from a group comprising a complex instruction set computer (CISC) microprocessor, a reduced instruction set computing (RISC) microprocessor, a very long instruction word (VLIW) microprocessor, and a processor implementing a combination of instruction sets.

23. The computer system of claim 16 wherein the computer system utilizes a JBus architecture.

24. The computer system of claim 16 wherein the electrical couplings are established by a plurality of pins and pin receptacles.

25. The computer system of claim 24 wherein the plurality of pin receptacles are holes.

26. The computer system of claim 16 wherein the PCB adapter card includes a matched impedance blade connector to maintain signal integrity.

27. A method of testing an integrated circuit (IC) assembly comprising:
providing a printed circuit board (PCB);
providing a plurality of flex circuit connections electrically coupled to the PCB;
providing a carrier electrically coupled to the PCB;
providing a socket electrically coupled to the carrier;
providing an application specific IC (ASIC) electrically coupled to the socket;
providing a PCB adapter card electrically couplable to at least one of the plurality of flex circuit connections, the PCB adapter card including at least one connector; and
providing a communication channel between the ASIC and a signal analyzer through the PCB adapter card connector.

28. The method of claim 27 further including changing only the carrier for a different type of ASIC.

29. The method of claim 27 further including changing only the PCB adapter card for a different type of signal analyzer.

30. The method of claim 27 wherein the ASIC is a central processing unit (CPU).

31. The method of claim 30 wherein the CPU is an mPGA-type CPU.

32. The method of claim 30 wherein the CPU is selected from a group comprising a complex instruction set computer (CISC) microprocessor, a reduced instruction set computing (RISC) microprocessor, a very long instruction word (VLIW) microprocessor, and a processor implementing a combination of instruction sets.

33. The method of claim 30 wherein the CPU is implemented in a JBus architecture.

34. The method of claim 27 further including soldering the PCB and the carrier together.

35. The method of claim 27 wherein the PCB adapter card includes a matched impedance blade connector to maintain signal integrity.
